(19) United States
(12) Patent Application Publication
(10) Pub. No.: US 2016/0343848 A1
(43) Pub. Date: Nov. 24, 2016

(54) Transistor Arrangement Including Power Transistors and Voltage Limiting Means

(71) Applicant: Infineon Technologies Dresden GmbH, Dresden (DE)

(72) Inventors: Martin Bartels, Dresden (DE); Marko Lemke, Dresden (DE); Ralf Rudolf, Dresden (DE); Stefan Tegen, Dresden (DE); Rolf Weis, Dresden (DE)

(21) Appl. No.: 15/158,126

(22) Filed: May 18, 2016

(30) Foreign Application Priority Data
May 21, 2015 (DE) 102015108091.5

(51) Int. Cl. H01L 29/78; H01L 29/08; H01L 29/10; H01L 27/06; H01L 29/40; H01L 29/739; H01L 29/866; H01L 29/06; H01L 29/423

(52) U.S. Cl. CPC H01L 29/7808; H01L 29/0696; H01L 29/0649; H01L 29/0882; H01L 29/1095; H01L 29/0865; H01L 29/4236; H01L 29/407; H01L 29/7811; H01L 29/7813; H01L 29/7397; H01L 29/866; H01L 27/0629

(57) ABSTRACT

A Transistor arrangement in a semiconductor body comprises a power transistor with at least two transistor cells, each transistor cell arranged in a semiconductor fin of the semiconductor body and with a voltage limiting device with at least two device cells. Each device cell is arranged adjacent a transistor cell in the semiconductor fin of the respective transistor cell and the voltage limiting device is separated from the power transistor by a dielectric layer.

Embodiments of the present invention relate to a transistor arrangement including power transistors and voltage limiting means.

Power transistors, in particular power field-effect transistors, such as power MOSFETs (Metal Oxide Field-Effect Transistors) or power IGBTs (Insulated Gate Bipolar Transistors) are widely used as electronic switches in drive applications, such as motor drive applications, or power conversion applications, such as AC/DC converters, DC/AC converters, or DC/DC converters.

There exist power transistors that are capable of blocking a high voltage and that have a low specific on-resistance (the on-resistance multiplied with the semi-conductor area (chip size) of the power transistor). In addition, there are minimum sized transistors for simple analog or logic circuitry, manufactured on the same wafer.

There is a need to provide a transistor arrangement with power transistors and voltage limiting means that keep the voltage over each power transistor below a given threshold.

One embodiment relates to a transistor arrangement in a semiconductor body. The transistor arrangement comprises a power transistor with at least two transistor cells, each transistor cell arranged in a semiconductor fin of the semiconductor body, and with a voltage limiting device with at least two device cells. Each device cell is arranged adjacent a transistor cell in the semiconductor fin of the respective transistor cell and the voltage limiting device is separated from the power transistor by a dielectric layer.

Examples are explained with reference to the drawings. The drawings serve to illustrate the basic principle, so that only aspects necessary for understanding the basic principle are illustrated. The drawings are not to scale. In the drawings the same reference characters denote like features.

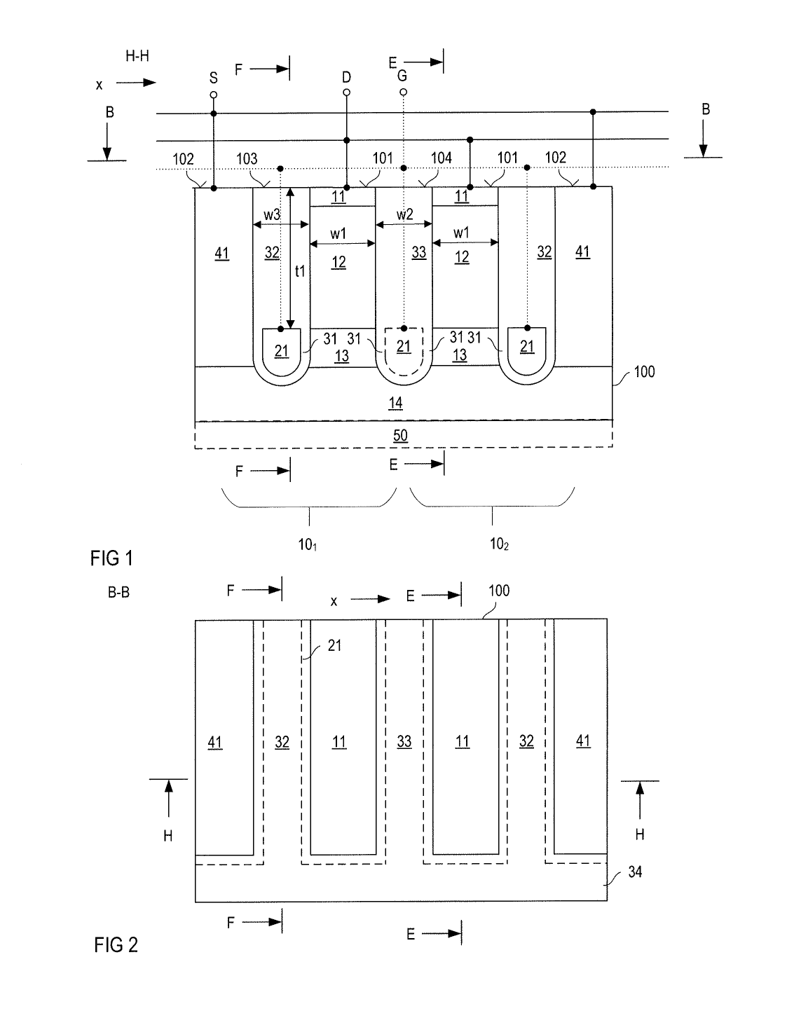

FIG. 1 illustrates a vertical cross sectional view of a power transistor according to one embodiment;

FIG. 2 illustrates a top view of the power transistor shown in FIG. 1;

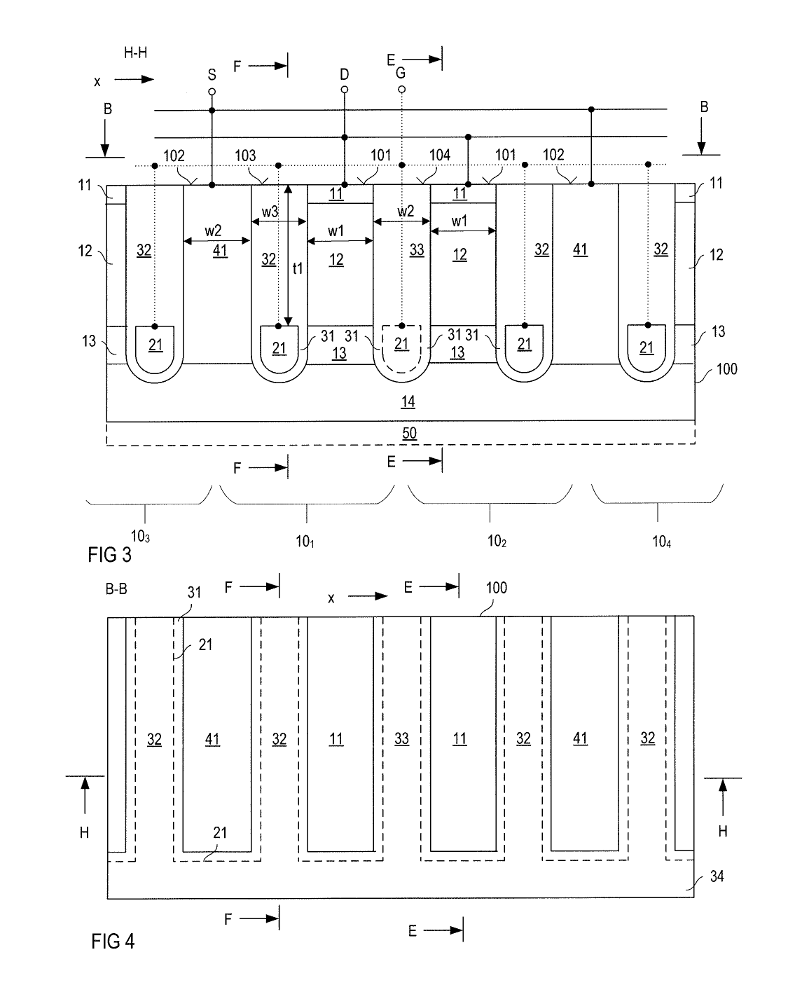

FIG. 3 illustrates a vertical cross sectional view of a power transistor according to another embodiment;

FIG. 4 illustrates a top view of the power transistor shown in FIG. 3;

FIG. 5 illustrates an equivalent circuit diagram of a power transistor and a voltage limiting device according to one embodiment;

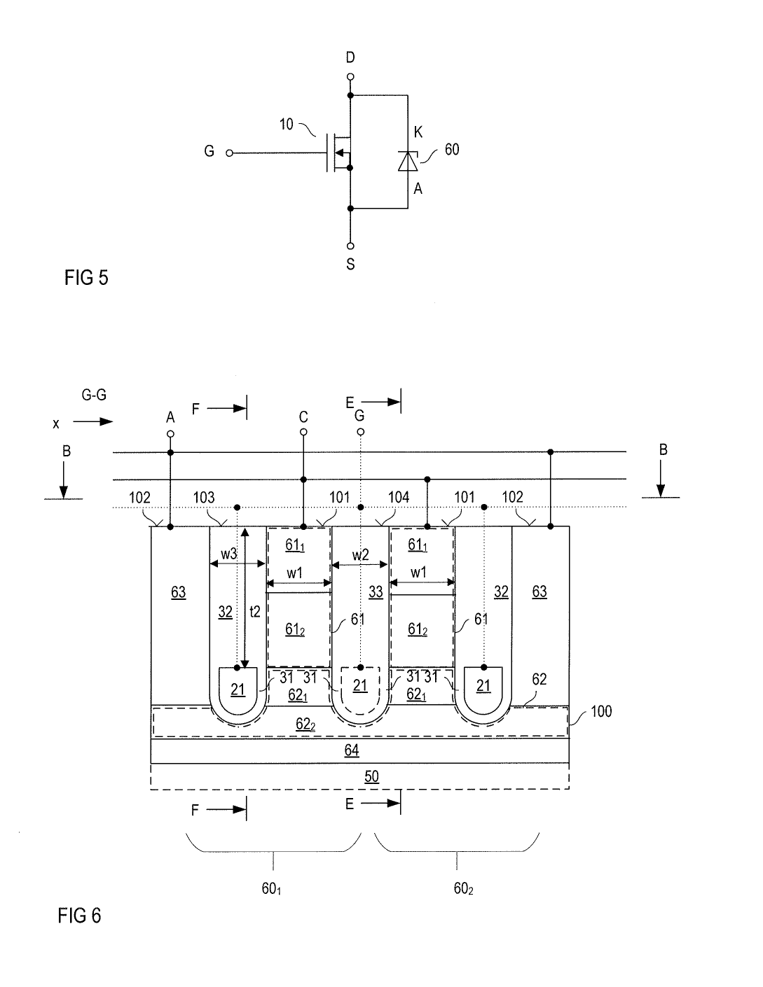

FIG. 6 illustrates a vertical cross sectional view of a voltage limiting device according to one embodiment;

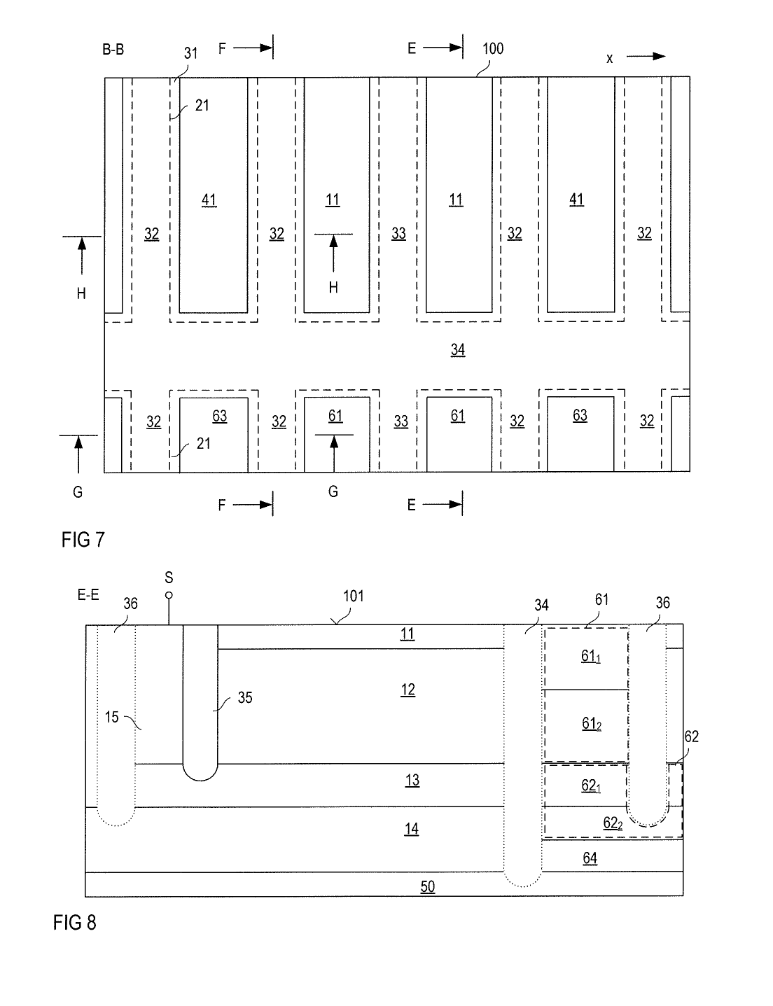

FIG. 7 illustrates a top view of a power transistor and a voltage limiting device according to one embodiment; and

FIG. 8 shows a vertical cross sectional view in a section plane perpendicular to the section planes shown in FIGS. 1, 3 and 5 of one of the power transistors shown in FIGS. 1 and 3 and one of the voltage limiting devices shown in FIG. 5, according to one embodiment;

In the following detailed description, reference is made to the accompanying drawings. The drawings form a part of the description and by way of illustration show specific embodiments in which the invention may be practised. It is to be understood that the features of the various embodiments described herein may be combined with each other, unless specifically noted otherwise.

FIGS. 1 and 2 illustrate a power transistor according to one embodiment. FIG. 1 shows a vertical cross sectional view of a portion of a semiconductor body 100 in which active device regions of the power transistor are integrated, and FIG. 2 shows a top view of the semiconductor body 100. Referring to FIGS. 1 and 2, the power transistor includes a plurality of substantially identical transistor cells. “Substantially identical” means that the individual transistor cells have identical device features, but may be different in terms of their orientation in the semiconductor body 100. In particular, the power transistor includes at least two transistor cells 10₁, 10₂ which, in the following, will be referred to as first and second transistor cells, respectively. In the following, when reference is made to an arbitrary one of the transistor cells or to the plurality of transistor cells, and when no differentiation between individual transistor cells is necessary, reference character 10 will be used to denote one or more of the plurality of transistor cells.

Referring to FIG. 1, each transistor cell 10 includes a drain region 11, a drift region 12 and a body region 13 in a semiconductor fin of the semiconductor body 100. Further, a source region 14 adjoins the body region 13 of each transistor cell 10. In the power transistor of FIG. 1 the individual transistor cells 10 have the source region 14 in common. That is, the source region 14 is a continuous semiconductor region which adjoins the body regions 13 of the individual transistor cells 10, wherein the body regions 13 (as well as the drain regions 11 and the drift regions 12) of the individual transistor cells 10 are separate semiconductor regions. It is, however, also possible that the source and/or the body region of each individual transistor may be structurally separated but electrically connected.

Referring to FIG. 1, each transistor cell 10 further includes a gate electrode 21 adjacent the body region 13 and dielectrically insulated from the body region 13 by a gate dielectric 31. Further, a field electrode 41 is dielectrically insulated from the drift region 12 by a field electrode dielectric 32 and is electrically connected to the source region 14.

FIGS. 3 and 4 illustrate a power transistor, which includes at least three transistor cells. Besides the first and second transistor cells 10₁, 10₂ explained with reference to FIGS. 1 and 2, the power transistor shown in FIGS. 3 and 4 includes a third transistor cell 10₃ adjacent to the first transistor cell 10₁. In the power transistor of FIGS. 3 and 4, two neighboring transistor cells share one field electrode 41. That is, one and the same field electrode 41 is dielectrically insulated from the drift region of one transistor cell by one field electrode dielectric 32, and is dielectrically insulated from the drift region 12 of another transistor cell by another field electrode dielectric 32. For example, the first transistor cell 10₁ and the third transistor cell 10₃ share one field electrode 41, so that the field electrode 41 of the first and third transistor cells 10₁, 10₃ is dielectrically insulated from the drift region 12 of the first transistor cell 10₁ by a field electrode dielectric 32 of the first transistor cell 10₁, and is dielectrically insulated from the drift region 12 of the neighboring third transistor cell 10₃ by the field electrode dielectric 32 of the third transistor cell 10₃. Equivalently, the second transistor cell 10₂ and a fourth transistor cell 10₄ adjacent the second transistor cell 10₂ share one field electrode, so that the field electrode 41 of the second and fourth transistor cells 10₂, 10₄ is dielectrically insulated from the drift region 12 of the second transistor cell 10₂ by a field electrode dielectric 32 of the second transistor cell 10₂, and is dielectrically insulated from the drift region 12 of the neighboring fourth transistor cell 10₄ by the field electrode dielectric 32 of the fourth transistor cell 10₄.

In the power transistors shown in FIGS. 1 and 3, the gate electrode 21, the gate dielectric 31, and the field electrode dielectric 32 of each transistor cell 10 (wherein in FIG. 3 reference character 10 represents transistors cells 10₁-10₄) are arranged in a first trench adjacent the drain region 11, the drift region 12, and the body region 13 of the corresponding transistor cell 10. The field electrode may terminate the power transistor in a lateral direction, or, as illustrated in FIG. 3, may be located between the first trenches of two transistor cells which share the field electrode 41.

In the power transistor shown in FIG. 3, the field electrode 41 shared by the first transistor cell 10₁ and the third transistor cell 10₃ is arranged between the first trench which accommodates the gate electrode 21, the gate dielectric 31 and the field electrode dielectric 32 of the first transistor cell 10₁ and the first trench which accommodates the gate electrode 21, the gate dielectric 31 and the field electrode dielectric 32 of the third transistor cell 10₃. Equivalently, the field electrode 41 shared by the second transistor cell 10₂ and the fourth transistor cell 10₄ is arranged between the first trench which accommodates the gate electrode 21, the gate dielectric 31 and the field electrode dielectric 32 of the second transistor cell 10₂ and the first trench which accommodates the gate electrode 21, the gate dielectric 31 and the field electrode dielectric 32 of the fourth transistor cell 10₄.

The semiconductor fin that includes the drain region 11, the drift region 12 and the body region 13 of the first transistor cell 10₁ is separated from the semiconductor fin which includes the drain region 11, the drift region 12, and the body region 13 of the second transistor cell 10₂ by a second trench which includes an electrically insulating, or dielectrically insulating material 33.

In the power transistors shown in FIGS. 1 and 3, the first transistor cell 10₁ and the second transistor cell 10₂ are substantially axially symmetric, with the symmetry axis going through the second trench with the insulating material 33. In the power transistor shown in FIG. 3, the first transistor cell 10₁ and the third transistor cell 10₃, as well as the second transistor cell 10₂ and the fourth transistor cell 10₄ are substantially axially symmetric, with the symmetry axis going through the common field electrode 41.

Referring to FIGS. 1 and 3, the individual transistor cells 10 are connected in parallel by having their drain regions 11 electrically connected to a drain node D, by having their gate electrodes 21 electrically connected through a gate node G, and by having the source region 14 connected to a source node S. An electrical connection between the drain regions 11 and the drain node D is only schematically illustrated in FIG. 1. This electrical connection can be implemented using conventional wiring arrangements implemented on top of a semiconductor body 100. Equivalently, an electrical connection between the field electrodes 41 and the source node S is only schematically illustrated in FIGS. 1 and 3. Electrical connections between the gate electrode 21 and the gate node G are illustrated in dotted lines in FIGS. 1 and 3. In the power transistors shown in FIGS. 1 and 3, these gate electrodes 21 are buried below the field electrode dielectric 32 in the first trenches.

In FIGS. 1 and 3, reference character 101 denotes surfaces of the semiconductor fins of the individual transistor cells 10. Reference character 102 denotes surfaces of the field electrodes 41, reference character 103 denotes surfaces of the field electrode dielectrics 32, and reference character 104 denotes surfaces of the insulating material 33 in the second trenches. According to one embodiment, these surfaces 101, 102, 103, and 104 are substantially in the same horizontal plane. The drain regions 11 may be contacted at the surfaces 101 in order to connect the drain regions 11 to the drain node D, and the field electrodes 41 may be contacted in the surfaces 102 in order to connect the field electrodes 41 to the common source node S.

When the transistor cells are in an off-state, the voltage applied over the at least two transistor cells is distributed such that a part of this voltage drops across each of the transistor cells. However, there may be cases in which there is no equal distribution of this voltage to the transistor cells. Instead, some transistor cells may have a higher voltage load than other transistor cells.

In order to more equally distribute the voltage to the transistor cells and keep the voltage applied to each transistor cell below a certain threshold, the transistor arrangement includes voltage limiting devices 60, that are configured to limit or clamp the voltage across the load paths (D-S) of the transistor cells.

Referring to FIG. 5, which shows an equivalent circuit diagram of a transistor cell and a voltage limiting element 60, the voltage limiting device 60 is connected between the drain and source terminals D, S of the transistor cell 10. According to one embodiment the voltage limiting device 60 is a Zener diode. A Zener diode is a diode which permits a current to flow in a forward direction. A Zener diode, as compared to bipolar diodes, further allows a current to flow in a reverse direction opposite the forward direction when a voltage level of a voltage applied between a cathode K and an anode A is above a certain threshold. This threshold is known as breakdown voltage, Zener voltage or avalanche point, for example. The voltage limiting device 60, however, may be implemented in many different ways. Still referring to FIG. 5, the Zener diode 60 is connected to the drain terminal D of the transistor cell 10 with its cathode K and to the source terminal S of the transistor cell 10 with its anode A.

FIG. 6 illustrates a voltage limiting device 60 according to one embodiment. FIG. 6 shows a vertical cross sectional view of a portion of the semiconductor body 100 in which the voltage limiting device 60 is integrated. FIG. 7 shows a top view of the semiconductor body 100 including a power transistor and a voltage limiting device. Referring to FIG. 6, the voltage limiting device includes a plurality of substantially identical device cells. “Substantially identical” means that the individual device cells have identical device features, but may be different in terms of their orientation in the semiconductor body 100. In particular, the voltage limiting device includes at least two device cells 60₁, 60₂, which, in the following, will be referred to as first and second device cells 60₁, 60₂, respectively. In the following, when reference is made to an arbitrary one of the device cells or the plurality of device cells, and when no differentiation between individual device cells is necessary, reference character 60 will be used to denote one or more of the plurality of device cells.

Referring to FIG. 6, each device cell 60 includes a cathode region 61 and an anode region 62 in a semiconductor fin of the semiconductor body 100. The cathode region 61 includes a first sub-region 61₁ and a second sub-region 61₂. The anode region 62 includes a third sub-region 62₁ and a fourth sub region 62₂. The first, second and third sub-regions 61₁, 61₂, 62₁ are arranged in a lateral extension of the semiconductor fin that includes the drain region 11, the drift region 12 and the body region 13 of a transistor cell 10. The fourth sub-region 62₂ adjoins the third sub-region 62₁ of each device cell 60. In the present embodiment, the individual device cells 60 have the fourth sub-region 62₂ in common. That is, the fourth sub-region 62₂ is a continuous semiconductor region which adjoins the third sub-regions 62₁ of the individual device cells 60, whereas the third sub-regions 62₁ (as well as the first and second sub-regions 61₁, 61₂) of the individual device cells 60 are separate semiconductor regions. Further, an additional semiconductor region 64 adjoins the fourth sub-region 62₂. The additional semiconductor region 64 also is a continuous semiconductor region.

Referring to FIGS. 6 and 7, the gate electrodes 21 of the transistor cells 10 extend further in a lateral direction into the device cells 60. Referring to FIG. 6 the gate electrodes 21 are arranged adjacent the anode regions 62 and are electrically insulated from the anode regions 62 by the gate dielectric 31. Further, an anode contacting region 63 is dielectrically insulated from the cathode region 61 by the field electrode dielectric 32 and is electrically connected to the anode region 62, in particular to the fourth sub-region 62₂. The cathode regions 61 of the first device cell 60₁ and the second device cell 60₂ are dielectrically insulated from each other by the field electrode dielectric 33.

In the embodiments shown in FIGS. 6 and 7, the gate electrode 21, the gate dielectric 31, and the field electrode dielectric 32 of each device cell 60 are arranged in the first trench adjacent the drain region 11, the drift region 12, and the body region 13 of the corresponding transistor cell 10, and adjacent the first sub-region 61₁, the second sub-region 61₂ and the third sub-region 62₁ of the corresponding device cell 60. The field electrode may terminate the power transistor and the voltage limiting device in a lateral direction, or, as illustrated in FIG. 7, may be located between the first trenches of two transistor cells which share the field electrode 41 and between the first trenches of two device cells which share the anode contacting region 63.

The semiconductor fin that includes the first sub-region 61₁, the second sub-region 61₂ and the third sub-region 62₁ of the first device cell 60₁ is separated from the semiconductor fin which includes the first sub-region 61₁, the second sub-region 61₂ and the third sub-region 62₁ of the second device cell 60₂ by the second trench which extends in lateral direction from the semiconductor region including the transistor cells 10.

In the embodiments shown in FIGS. 6 and 7, the first device cell 60₁ and the second device cell 60₂ are substantially axially symmetric, with the symmetry axis going through the second trench with the insulating material 33.

Referring to FIGS. 7 and 8, the transistor cells 10 and the device cells 60 are electrically insulated from each other by a separating dielectric 34. Referring to FIGS. 6 and 7, the gate electrode 21, the gate dielectric 31, the field electrode dielectric 32 and the field electrode dielectric 33 of the transistor cells 10 stretch across and beyond the separating dielectric 34 into the device cells. The gate electrode 21 and the gate dielectric 31 may further stretch across a length of the separating dielectric 34. Referring to FIG. 7, seen from above, the gate electrode 21 may have a comb-like shape, having teeth to both sides which stretch into the transistor cells 10 to one side and into the device cells 60 to the other side.

Referring to FIG. 6, the individual device cells 60 are connected in parallel by having their cathode regions 61 electrically connected to a cathode node C and by having their anode regions 62 electrically connected to an anode node A. An electrical connection between the cathode regions 61 and the cathode node C is only schematically illustrated in FIG. 6. This electrical connection can be implemented using conventional wiring arrangements implemented on top of a semiconductor body 100. Equivalently, an electrical connection between the anode region 62 and the anode node A is only schematically illustrated in FIG. 6. Further, the cathode node C may be electrically connected to the drain node D of the transistor cells 10 and the anode node A may be electrically connected to the source node S of the transistor cells. These electrical connections can also be implemented using conventional wiring arrangements implemented on top of a semiconductor body 100.

Referring to FIG. 6, as the gate electrodes 21 extend from a transistor cell 10 across the separating dielectric 34 into a device cell 60 and are arranged adjacent a third sub-region 62₁ of the respective device cell 60, so that a MOS gated diode (MGD) is formed. An MGD, also called gate-controlled diode or gated diode, is a semiconductor device that combines the function of a p-n junction and a MOS transistor. The gate electrode 21, that is arranged in close proximity of the junction between the cathode region 61 and the anode region 62, generates a conducting channel in the third sub-region 62₁ between the second sub-region 61₂ and the fourth sub-region 62₂ each time the electrical potential of the cathode region 61 is more than a threshold voltage of the MGD above the electrical potential of the anode region 62. The threshold voltage of the MGD is lower than the forward voltage of the voltage limiting device 60, so that the MGD bypasses the voltage limiting device 60 before the voltage limiting device 60 is forward biased.

Referring to FIGS. 1, 3 and 6, the semiconductor fin of each transistor cell 10 and each voltage limiting element 60 has a first width w1. This first width w1 corresponds to the distance between the first trench adjoining the semiconductor fin and accommodating the field electrode dielectric 32 and the second trench adjoining the semiconductor fin and accommodating the insulating material 33. According to one embodiment, the first width w1 is selected from a range of between 10 nm (nanometers) and 100 nm. According to one embodiment, the semiconductor fins of the individual transistor cells 10 and the voltage limiting elements 60 have substantially the same first width w1. According to another embodiment, the first widths w1 of the individual semiconductor fins are mutually different. According to another embodiment, the first width w1 of the semiconductor fins of the transistor cells 10 is different to the first width of the semiconductor fins of the device cells 60.

A second width w2 of the field electrode 41 and the anode contacting region 63 may be in the same range explained with reference to the first width w1 above when the field electrode 41 is shared by two transistor cells, as illustrated in FIG. 3. When the field electrode 41 terminates a cell region with several transistor cells it may be wider. A third width w3 of the field electrode dielectric 32 is, for example, between 30 nm and 300 nm. As, referring to FIGS. 1, 3 and 6, the field electrode dielectric 33 fills the trench above the gate electrode 21 and the gate dielectric 31, the width w3 of the field electrode dielectric 33 is greater than a thickness of the gate dielectric 31.

The first width w1 is the dimension of the semiconductor fin in a first horizontal direction x of the semiconductor body 100. Referring to FIGS. 2, 4 and 7, which show top views of the semiconductor body 100, the semiconductor fin with the drain region 11, the drift region 12 and the body region 13 (whereas FIGS. 2,4 and 7 only show the drain region 11) has a length in a direction perpendicular to the first horizontal direction x. The extension of the semiconductor fin with the cathode region 61 and third sub-region 62₁ (whereas FIG. 7 only shows the cathode region 61) also has a length in a direction perpendicular to the first horizontal direction x. In FIGS. 2, 4 and 7, the dotted lines show the position of the gate electrodes 21 in the first trenches below the field electrode dielectric 32 and below the separating dielectric 34. According to one embodiment, the length of the semiconductor fin and its extension is much longer than the first width w1. According to one embodiment, a ratio between the length and the width w1 is at least 2:1, at least 100:1, at least 1000:1, or at least 10000:1. The same applies to a ratio between a length of the field electrode 41 and the corresponding width w2 and a length of the field electrode dielectric 32 and the corresponding width w3, including a length of the corresponding extensions of the semiconductor fins, respectively.

The characteristics of the MGD may be optimized in terms of its switch-on behavior by reducing the thickness t1, t2 of the field electrode dielectric 32 in a vertical direction. According to one embodiment, the thickness t1 of the field electrode dielectric 32 insulating the field electrode 41 from the drift region 12 of the transistor cells 10 may be between about 30 to 70 nm. Whereas the thickness t2 of the field electrode dielectric 32 insulating the cathode region 61 from the anode contacting region 63 of the device cells 60 may be between about 1.5 to 10 nm. The field electrode dielectric 32 may therefore have a different thickness t1, t2 in different parts of the semiconductor body 100. Reducing the thickness of the field electrode dielectric 32 in parts of the device cells 60 may include an etching process, in particular an isotropic etching process.

The power transistor shown in FIGS. 1-4 is a FET (Field-Effect Transistor) and, more specifically, a MOSFET (Metal Oxide Field-Effect Transistor) or an IGBT (Insulated Gate Bipolar Transistor). It should be noted that the term MOSFET as used herein denotes any type of field-effect transistor with an insulated gate electrode (often referred to as IGFET) independent of whether the gate electrode includes a metal or another type of electrically conducting material, and independent of whether the gate dielectric includes an oxide or another type of dielectrically insulating material. The drain regions 11, drift region 12, body regions 13, and the source region 14 of the individual transistor cells 10 as well as the cathode regions 61 and anode regions 62 of the individual device cells 60 may include a conventional monocrystalline semiconductor material such as, for example, silicon (Si), germanium (Ge), silicon carbide (SiC), gallium nitride (GaN), gallium arsenide (GaAs), or the like. The gate electrodes 21 may include a metal, TiN, carbon or a highly doped polycrystalline semiconductor material, such as polysilicon or amorphous silicon. The gate dielectrics 31 may include an oxide such as, for example, silicon dioxide (SiO₂), a nitride such as, for example, silicon nitride (Si3N4), an oxinitride or the like. Like the gate electrodes 21, the field electrodes 41 may include a metal, TiN, carbon or a highly doped polycrystalline semiconductor material. Like the gate dielectrics 31, the field electrode dielectrics 32 and the separating dielectric 34 may include an oxide or a nitride or an oxinitride. The same applies to the insulating material 33.

The power transistor can be implemented as an n-type transistor, or as a p-type transistor. In the first case, the source region 14 and the drift region 12 of each transistor cell 10 is n-doped. In the second case, the source region 14 and the drift region 12 of each transistor cell 10 is p-doped. Further, the transistor can be implemented as an enhancement (normally-off) transistor, or as a depletion (normally-on) transistor. In the first case, the body regions 13, have a doping type complementary to the doping type of the source region 14, and the drift region 12. In the second case, the body region 13 has a doping type corresponding to the doping type of the source 14 and the drift region 12. Further, the transistor can be implemented as a MOSFET or as an IGBT. In a MOSFET, the drain region has the same doping type as the source region. An IGBT (Insulated Gate Bipolar Transistor) is different from a MOSFET in that the drain region 11 (which is also referred to as collector region in an IGBT) has a doping type complementary to the doping type of the source and drift regions 14, 12. The cathode region 61 may be n-doped, with the first sub-region 61₁ more heavily doped than the second sub-region 61₂. The anode region may be p-doped, with the fourth sub-region 62₂ more heavily doped than the third sub-region 62₁. The cathode region 61 and the anode region 62, in particular the second sub-region 61₂ and the third sub-region 62₁, form a p-n junction. The additional semiconductor region 64 may be n-doped.

The doping concentration of the drain regions 11 is, for example, between 1E19 cm⁻³ and 1E21 cm⁻³, the doping concentration of the drift region 12 is, for example, between 1E14 cm⁻³ and 1E19 cm⁻³, the doping concentration of the body region 13 is, for example, between 1E14 cm⁻³ and 1E18 cm⁻³, and the doping concentration of the source region 14 is, for example, between 1E17 cm⁻³ and 1E21 cm⁻³. The doping concentration of the first sub-region 61₁ is, for example, between 1E15 cm⁻³ and 1E21 cm⁻³, the doping concentration of the second sub-region 61₂ is, for example, between 1E13 cm⁻³ and 1E18 cm⁻³, the doping concentration of the third sub-region 62₁ is, for example, between 1E13 cm⁻³ and 1E18 cm⁻³ and the doping concentration of the fourth sub-region 62₂ is, for example, between 1E15 cm⁻³ and 1E21 cm⁻³.

Referring to FIGS. 1 and 3, the source region 14 is a buried semiconductor region (semiconductor layer), which is distant to the surfaces 101 of the individual semiconductor fins. Referring to FIG. 6, the additional semiconductor region 64 is a buried semiconductor region (semiconductor layer), which is distant to the surfaces 101 of the individual semiconductor fins. According to one embodiment (illustrated in dashed lines in FIGS. 1, 3 and 6), the source region 14 and the additional semiconductor region 64 adjoin a carrier 50 which may provide for a mechanical stability of the power transistor. According to one embodiment, the carrier 50 is a semiconductor substrate. This semiconductor substrate may have a doping type complementary to the doping type of the source region 14 and the additional semiconductor region 64. According to another embodiment, a carrier 50 includes a semiconductor substrate and an insulation layer on the substrate. In this embodiment, the source region 14 and the additional semiconductor region 64 may adjoin the insulation layer of the carrier 50.

The power transistor shown in FIG. 1 can be operated like a conventional field-effect transistor, that is, like a conventional MOSFET or conventional IGBT. The power transistor can be switched on or switched off by applying a suitable drive potential to the individual gate electrodes 21 via the gate node G. The power transistor is switched on (is in an on-state) when the drive potential applied to the gate electrodes 21 is such that there is a conducting channel in the body regions 13 between the source region 14 and the drift regions 12. When the power transistor is implemented as an enhancement transistor, there is a conducting channel in the body region 13 of each transistor cell when the corresponding gate electrode 21 is biased such that there is an inversion channel in the body region 13 along the gate electrode dielectric 31. For example, in an n-type enhancement transistor, the drive potential to be applied to the gate electrode 21 in order to switch on the transistor is an electrical potential which is positive relative to the electrical potential at the source node S. In a depletion transistor there is a conducting channel in the body region 13 of each transistor cell 10 when the gate electrode 21 is biased such that the gate electrode 21 does not cause the body region 13 to be depleted. For example, in a depletion transistor, the electrical potential at the gate electrode 21 may correspond to the electrical potential at the source node S in order to switch on the transistor.

When the power transistor is in the off-state and a voltage is applied between the drain and source nodes D, S, a depletion region (space-charge region) may expand in the drift region 12 beginning at the body region 13. For example, in an n-type transistor, a depletion region expands in the drift region 12 when a positive voltage is applied between the drain and source nodes D, S, and when the transistor is in the off-state. A depletion region expanding the drift region 12 is associated with ionized dopant atoms in the drift region 12. In the power transistor shown in FIG. 1, a part of these ionized dopant atoms in the drift region 12 finds corresponding counter charges in the field electrode 41. This effect is known from field-effect transistors having a field electrode (field plate) adjacent a drift region. The field electrode, such as the field electrode 41 shown in FIG. 1, allows to implement the power transistor with a doping concentration of the drift region 12 higher than the doping concentration of a comparable power transistor without field electrode, without reducing the voltage blocking capability. The higher doping concentration of the drift region 11, however, provides for a lower on-resistance of the power transistor.

In the embodiments shown in FIGS. 1 and 3, the gate electrode 21 of each transistor cell 10 is arranged in the first trench, adjacent the body region 13 and dielectrically insulated from the body region 13 by the gate dielectric 31. In the embodiment shown in FIG. 6, the gate electrode 21 is further arranged adjacent the anode region 62 and is dielectrically insulated from the anode region 62 by the gate dielectric 31, respectively. According to another embodiment (illustrated in dashed lines in FIGS. 1, 3 and 6) the gate electrode 21 of one transistor cell and one device cell 60 is not only arranged in the first trench but is also arranged in the second trench below the insulating material 33, adjacent the body region 13 and the third sub-region 62₁, and dielectrically insulated from the body region 13 and the third sub-region 62₁, by the gate dielectric 31. Like the gate electrode 21 in the first trench, the gate electrode 21 in the second trench is connected to the gate node G.

FIG. 8 shows a vertical cross sectional view (in section plane E-E shown in FIGS. 1, 3 and 6) of a semiconductor fin of one transistor cell 10 and one device cell 60 according to one embodiment. In this embodiment, the body region 13 is electrically connected to the source node S through a contact region 15 which extends from the surface 101 of the semiconductor fin down to the body region 13. In the longitudinal direction of the semiconductor fin, the contact region 15 is electrically or dielectrically insulated from the drain and drift regions 11, 12 by an insulation layer 35. This insulation layer is arranged in a trench which extends from the surface of the semiconductor fin down to the body region 13. According to one embodiment, the contact region 15 is located near a longitudinal end of the semiconductor fin. In the embodiment shown in FIG. 8, the longitudinal ends of the semiconductor fin are formed by trenches which extend from the surface 101 down to the source region 14 (or even beyond the source region 14) and down to the fourth sub-region 62₂, respectively, and are filled with an electrically or dielectrically insulating material 36. According to one embodiment, the separating dielectric 34 is formed by a trench which extends from the surface 101 down to the carrier 50 and is filled with an electrically or dielectrically insulating material.

It is to be understood that the features of the various embodiments described herein may be combined with each other, unless specifically noted otherwise.

1. A transistor arrangement in a semiconductor body, the transistor arrangement comprising:
a power transistor with at least two transistor cells, each transistor cell arranged in a semiconductor fin of the semiconductor body;
a voltage limiting device with at least two device cells;
wherein each device cell is arranged adjacent a transistor cell in the semiconductor fin of the respective transistor cell, wherein the voltage limiting device is separated from the power transistor by a dielectric layer.

2. The transistor arrangement according to claim 1, wherein each transistor cell comprises
a drain region, a drift region, and a body region in a semiconductor fin of a semiconductor body;
a source region adjoining the body region;
a gate electrode adjacent the body region and dielectrically insulated from the body region by a gate dielectric;
a field electrode dielectrically insulated from the drift region by a field electrode dielectric, and connected to the source region, wherein the field electrode dielectric is arranged in a first trench between the semiconductor fin and the field electrode;
wherein the at least two transistor cells comprise a first transistor cell, and a second transistor cell, and
wherein the semiconductor fin of the first transistor cell is separated from the semiconductor fin of the second transistor cell by a second trench different from the first trench.

3. The transistor arrangement of claim 1, wherein each device cell comprises a cathode region, an anode region and an additional semiconductor region adjoining the anode region, wherein the at least two device cells comprise a first device cell and a second device cell.

4. The transistor arrangement of claim 3, wherein the cathode region comprises a first sub-region and a second sub-region;

5. The transistor arrangement of claim 3, wherein the anode region comprises a third sub-region and a fourth sub-region.

6. The transistor arrangement of claim 3, wherein the gate electrode and the gate dielectric extend from a transistor cell into a device cell adjacent the anode region, the gate dielectric dielectrically insulating the gate electrode from the anode region.

7. The transistor arrangement of claim 2, wherein the at least two transistor cells are connected in parallel by having the gate electrode of each transistor cell connected to a gate node, by having the drain region of each transistor cell connected to a drain node, and by having the field electrode of each transistor cell connected to a source node.

8. The transistor arrangement of claim 3, wherein the at least two device cells are connected in parallel by having the cathode region of each device cell connected to a cathode node, and by having the anode region of each device cell connected to an anode node.

9. The transistor arrangement of claim 8, wherein the power transistor device and the voltage limiting device are connected in parallel by having the cathode node connected to the drain node, and by having the anode node connected to the source node.

10. The transistor arrangement of claim 3, wherein the cathode region has a doping type complementary to the doping type of the anode region.

11. The transistor arrangement of claim 4, wherein the first sub-region is more heavily doped than the second sub-region.

12. Transistor arrangement of claim 5, wherein the fourth sub-region is more heavily doped than the third sub-region.

13. The transistor arrangement of claim 1,
wherein the semiconductor fin has a width and a length,
wherein a ratio between the length and the width is selected from one of
at least 2:1,
at least 100:1,
at least 1000:1, and
at least 10000:1.

14. The transistor arrangement of claim 1, wherein the number of the plurality of transistor cells and the number of the plurality of device cells is selected from one of
at least 100,
at least 1000, and
at least 10000.

15. The transistor arrangement of claim 14, wherein the number of the plurality of transistor cells is equal to the number of the plurality of device cells.

16. The transistor arrangement of claim 1, wherein the voltage limiting device is selected from one of
a Zener diode, and
an avalanche diode.

17. The transistor arrangement of claim 3, wherein each device cell further comprises an anode contacting region, dielectrically insulated from the cathode region by the field electrode dielectric and electrically connected to the anode region.

18. The transistor arrangement of claim 17, wherein
a thickness of the field electrode dielectric in parts of the semiconductor body where it insulates the field electrode from the drift region of the transistor cells is greater than a thickness of the field electrode dielectric in parts of the semiconductor body where it insulates the cathode region from the anode region of the device cells.

19. The transistor arrangement of claim 18, wherein
the thickness of the field electrode dielectric in parts of the semiconductor body where it insulates the field electrode from the drift region of the transistor cells is between 30 to 70 nm; and
the thickness of the field electrode dielectric in parts of the semiconductor body where it insulates the cathode region from the anode contacting region of the device cells is between 1.5 to 10 nm.
